(19) United States
(12) Patent Application Publication
(10) Pub. No.: US 2025/0063716 A1
(43) Pub. Date: Feb. 20, 2025

(54) STORAGE NODE CONTACT (SNC) JUNCTION FORMATION FOR THREE-DIMENSIONAL DYNAMIC RANDOM ACCESS MEMORY (DRAM)

(71) Applicant: Applied Materials, Inc., Santa Clara, CA (US)

(72) Inventors: Zhijun CHEN, San Jose, CA (US); Fredrick FISHBURN, Aptos, CA (US)

(21) Appl. No.: 18/781,132

(22) Filed: Jul. 23, 2024

Related U.S. Application Data
(60) Provisional application No. 63/520,357, filed on Aug. 18, 2023.

(51) Int. Cl. H10B 12/00

(52) U.S. Cl. CPC H10B 12/03; H10B 12/315

(57) ABSTRACT

Examples herein relate to three-dimensional (3D) dynamic random access memory (DRAM) and corresponding methods. In an example, a stacked semiconductor structure is provided, where the stacked semiconductor structure includes a plurality of unit stacks formed on a substrate. Each unit stack has a semiconductor layer, a first dielectric layer, a first gate electrode, and a second dielectric layer of a capacitor portion. A lateral recess of the capacitor portion is open to a first opening through the unit stack. The method includes conformally depositing, in the lateral recess, a doped silicon layer on a lateral end of the semiconductor layer, performing a thermal annealing process after forming the doped silicon layer on the second lateral end. The method further includes forming a capacitor where the lateral recess was disposed, the capacitor contacting the doped silicon layer on the second lateral end of the semiconductor layer.

### CROSS-REFERENCE TO RELATED APPLICATIONS

This application claims the benefit of United Stated Provisional Patent Application Ser. No. 63/520,357 filed Aug. 18, 2023, which is hereby incorporated by reference.

### BACKGROUND

### Field

Examples described herein generally relate to the field of semiconductor processing, and more specifically, to three-dimensional (3D) dynamic random access memory (DRAM) and methods of forming storage node contact (SNC) junctions for 3D DRAM.

### Description of the Related Art

Technology advances in semiconductor processing have resulted in integrated circuits reaching the physical limits of Moore's Law. These advances have resulted in new paradigms for devices and structures in integrated circuits. For example, various three-dimensional (3D) designs are being developed for DRAM. However, such 3D devices can result in a new set of challenges for processing and fabrication.

### SUMMARY

Embodiments of the disclosure include a method for semiconductor processing. A stacked semiconductor structure is provided. The stacked semiconductor structure includes a plurality of unit stacks formed on a substrate, each unit stack having a transistor portion and a capacitor portion laterally adjacent the transistor portion. The transistor portion has a semiconductor layer, a first dielectric layer formed on the semiconductor layer, and a first gate electrode formed on the first dielectric layer. The first gate electrode extends through a row of memory cells of a memory device, the first gate electrode to form a gate structure with the semiconductor layer. A first lateral end of the semiconductor layer is doped and coupled with a bitline node of the memory device. A second lateral end of the semiconductor layer is opposite the first lateral end, the second lateral end adjacent a lateral recess formed in a second dielectric layer of the capacitor portion. A doped silicon layer is conformally deposited in the lateral recess, including on the second lateral end of the semiconductor layer. An optional thermal annealing process is performed after forming the doped silicon layer on the second lateral end. A capacitor is formed in the capacitor region where the lateral recess was disposed, the capacitor contacting the doped silicon layer on the second lateral end of the semiconductor layer.

Embodiments of the disclosure also include another method for semiconductor processing. The method includes providing a stacked semiconductor structure, where the stacked semiconductor structure includes a plurality of unit stacks formed on a substrate. Each unit stack has a semiconductor layer having a first lateral end and a second lateral end, a first dielectric layer formed on the semiconductor layer, a first gate electrode formed on the first dielectric layer, and a second dielectric layer of a capacitor portion. A lateral recess is bounded by the second dielectric layer at a top and a bottom and by the second lateral end of the semiconductor layer at a first side. The lateral recess is open to a first opening through the unit stack of the stacked semiconductor structure at a second side. The method further includes conformally depositing, in the lateral recess, a doped silicon layer on the second lateral end of the semiconductor layer. The method further includes performing an optional thermal anneal process after forming the doped silicon layer on the second lateral end. The method further includes forming a capacitor where the lateral recess was disposed, the capacitor contacting the doped silicon layer on the second lateral end of the semiconductor layer.

Embodiments of the disclosure also include another method for semiconductor processing. The method includes forming a stacked semiconductor structure including a plurality of unit stacks formed on a substrate. Each unit stack includes a semiconductor layer, a first dielectric layer formed on the semiconductor layer, and a second dielectric layer of a capacitor portion of the stacked semiconductor structure, the semiconductor layer having a first lateral end and a second lateral end opposite the first later end. The method further includes forming a first opening through the unit stack. The method further includes pulling back the second dielectric layer from the first opening to form a lateral recess exposing the second lateral end of the semiconductor layer. The method further includes conformally depositing a doped silicon layer in the lateral recess, including a vertical portion on the second lateral end and lateral portions coupled with the vertical portion. The method further includes forming a third dielectric layer on the doped silicon layer in the lateral recess. The method further includes pulling back the third dielectric layer to expose the vertical portions of the doped silicon layer. The method further includes pulling back the vertical portion and the lateral portions of the doped silicon layer. The method further includes removal (e.g. complete removal) of the sacrificial third dielectric layer. The method further includes performing an optional thermal anneal process after conformally depositing the doped silicon layer, or after third dielectric layer deposition, or after pulling back the doped silicon layer, or after full removal of the sacrificial third dielectric layer.

### BRIEF DESCRIPTION OF THE DRAWINGS

So that the manner in which the above recited features of the present disclosure can be understood in detail, a more particular description, briefly summarized above, may be had by reference to examples, some of which are illustrated in the appended drawings. It is to be noted, however, that the appended drawings illustrate only some examples and are therefore not to be considered limiting of the scope of this disclosure, for the disclosure may admit to other equally effective examples.

FIG. 1 is a circuit schematic of a dynamic random access memory (DRAM) cell according to some examples of the present disclosure.

FIG. 2 is a perspective view of a mirrored DRAM pair according to some examples of the present disclosure.

FIG. 3 is a perspective view of a mirrored DRAM pair according to some examples of the present disclosure.

FIGS. 4 through 10 are cross-sectional views of intermediate structures during a method to form memory devices, such as 3D DRAM cells, according to some examples of the present disclosure.

FIGS. 11 through 13 are flow diagrams of methods of semiconductor processing, according to one or more embodiments.

To facilitate understanding, identical reference numerals have been used, wherever possible, to designate identical elements that are common to the figures.

### DETAILED DESCRIPTION

Examples described herein generally relate to the field of semiconductor processing, and more specifically, to memory devices, including three-dimensional (3D) dynamic random access memory (DRAM) and methods for semiconductor processing, including forming storage node contact (SNC) junctions for memory devices, such as 3D DRAM. According to various examples, a stacked semiconductor structure is formed on a substrate. The stacked semiconductor structure includes multiple unit stacks (e.g., up to one hundred or more unit stacks), where each unit stack includes layers selected from a group of different materials and repeats the structure of the unit stack vertically (e.g., each unit stack a transposition or vertical mirror of an adjacent unit stack), each unit stack including one or more semiconductor layers and one or more dielectric layers. The unit stack is used to form memory devices, such as 3D DRAM devices. Specifically, the stacked semiconductor structure is used to form vertically stacked memory devices having a capacitor structure (e.g., a capacitor portion) laterally disposed from a transistor (e.g., a transistor portion) of the unit stack. The formation of the memory device of a unit stack uses doping the semiconductor layer that is laterally positioned in a recessed cavity that is down an opening in the film stack, the recessed cavity formed by pulling back the semiconductor layer in the unit stack. A doped silicon layer is conformally deposited in the recessed cavity, including on a portion of the semiconductor layer exposed to the recessed cavity (e.g., a vertical portion of the semiconductor layer). In one example, the doped silicon layer is a doped amorphous silicon layer. In another example, the doped silicon layer is a doped polycrystalline layer. Optionally, an undoped silicon layer can be deposited before the doped silicon layer mentioned above. An optional thermal annealing process (e.g., a rapid thermal processing operation) is then performed on the stacked semiconductor structure. Dopant (e.g., phosphorous, arsenic) from the doped silicon layer may thus be driven into the semiconductor layer and/or the optional undoped silicon layer by the thermal annealing process to form a source or drain region. A drain or source region in the semiconductor layer may have been previously formed opposite the formed source or drain region, respectively. A capacitor is then formed in the capacitor region the recessed cavity, the deposited doped silicon layer forming a part of a contact to the capacitor from the transistor.

The semiconductor processing as described herein, including the formation of the stacked semiconductor structure, can ensure dopant implantation in non-line of sight locations during formation of a memory device, such as a 3D DRAM device, having recessed cavities during formation. Additionally the semiconductor processing described herein can provide desired doping levels in laterally recessed cavities during formation of the memory devices, for example where the lateral width of the recess exceeds the vertical height of the recess, such as in high-aspect ratio lateral recesses.

Additionally, various numbers of vertically stacked memory devices can be achieved without adding further different materials, and differently sized capacitors (e.g., having different capacitance values) can implemented consistent with the disclosure herein while maintaining a same or substantially similar set of process steps. Different examples herein can also achieve single or double gated transistors for 3D DRAM.

Various different examples are described below. Although multiple features of different examples may be described together in a process flow or system, the multiple features can each be implemented separately or individually and/or in a different process flow or different system. Additionally, various process flows are described as being performed in an order; other examples can implement process flows in different orders and/or with more or fewer operations. Additionally, although source and drain nodes and source and drain regions are described in various examples, such description can more generally be to a source/drain node or source/drain region. Further, in some examples, n-type transistors are described, and more generally, any type of transistor (e.g., p-type transistors) can be implemented.

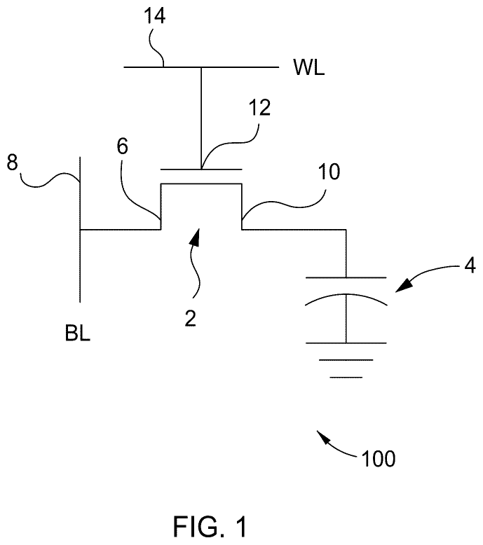

FIG. 1 is a circuit schematic of a dynamic random access memory (DRAM) cell 100 according to some examples of the present disclosure. The DRAM cell 100 includes an n-type transistor 2 and a capacitor 4. A first node 6 (e.g., a drain node) of the n-type transistor 2 is electrically connected to a bitline (BL) node 8. A second node 10 (e.g., a source node) of the n-type transistor 2 is electrically connected to a first terminal of the capacitor 4, and a second terminal of the capacitor 4 (opposite from the first terminal) is electrically connected to a power supply node (e.g., a ground node). A gate node 12 of the n-type transistor 2 is electrically connected to a wordline (WL) node 14.

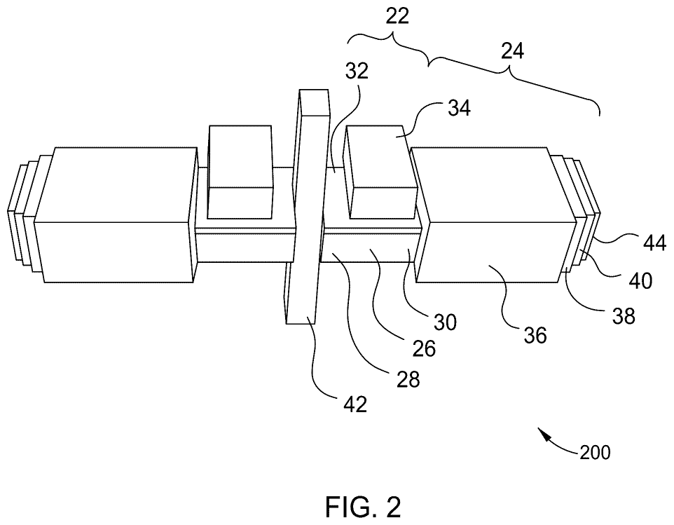

FIG. 2 is a perspective view of a mirrored DRAM pair 200 according to some examples of the present disclosure. FIG. 2 depicts two DRAM cells that are mirrored along a vertical axis, which may be referred to herein for convenience as a mirrored DRAM pair 200. As will become apparent in subsequent description, multiple mirrored DRAM pairs (e.g., two pairs, three pairs, etc.) may be stacked vertically in a DRAM structure. To avoid unnecessarily obscuring aspects of the figures, one DRAM cell of a mirrored DRAM pair is labeled with reference numbers, and a person having ordinary skill in the art will readily understand mirrored components in the other DRAM cell of the mirrored DRAM pair.

A DRAM cell includes an n-type transistor 22 (e.g., corresponding to n-type transistor 2) and a capacitor 24 (e.g., corresponding to capacitor 4). The n-type transistor 22 includes a semiconductor layer 26 that forms the active region of the n-type transistor 22. In one or more embodiments, the semiconductor layer 26 is p-doped, for example lightly p-doped (e.g., less than about 1 atom per 100 million atoms). In other embodiments, the semiconductor layer 26 is un-doped. A first region 28 (e.g., corresponding to first node 6) and a second region 30 (e.g., corresponding to second node 10) are disposed in the semiconductor layer 26 with a channel region between the first region 28 and the second region 30 in the semiconductor layer 26. In one or more embodiments, the first region 28 is a drain region, the first node 6 is a drain node, the second region 30 is a source region, and the second node 10 is a source node in some circumstances (e.g., when programming the cell with a one charge). In other circumstances (e.g., when programming the cell with a zero charge), the first region 28 is a source region, the first node 6 is a source node, the second region 30 is a drain region, and the second node 10 is a drain node. The first region 28 and the second region 30 are n-doped in this example. A gate dielectric layer, first dielectric layer 32, is disposed on the semiconductor layer 26 (e.g., on a top surface of the semiconductor layer 26), and a gate electrode 34 (e.g., corresponding to gate node 12) is disposed on the first dielectric layer 32.

The capacitor 24 includes an outer plate 36 (e.g., corresponding to a first terminal of capacitor 4), a capacitor dielectric layer 38, and an inner plate 40 (e.g., corresponding to a second terminal of capacitor 4). The outer plate 36 is a conductive material, such as a metal or metal-containing material. The outer plate 36 generally has the shape of a single-capped cylinder, single-capped rectangular prism, or the like. The outer plate 36 generally extends laterally from the n-type transistor 22 and has a capped end that contacts the second region 30 of the n-type transistor 22 to electrically connect the second region 30 to the capacitor 24. The end of the outer plate 36 opposite from the n-type transistor 22 is open. The capacitor dielectric layer 38 is a dielectric material that is disposed conformally along interior surfaces of the outer plate 36. The dielectric material of the capacitor dielectric layer 38 can be a high-k dielectric material (e.g., having a k-value greater than 4.0). The inner plate 40 is a conductive material, such as a metal or metal-containing material, and is disposed on the capacitor dielectric layer 38 and fills a remaining interior portion of the outer plate 36.

A bitline contact 42 (e.g., corresponding to BL node 8) is disposed laterally contacting the first region 28 of the n-type transistor 22. The bitline contact 42 extends vertically, and the vertical axis along which the mirror DRAM pair is mirrored extends along the bitline contact 42. A power supply contact 44 (e.g., a ground contact) is disposed laterally contacting the inner plate 40 of the capacitor 24.

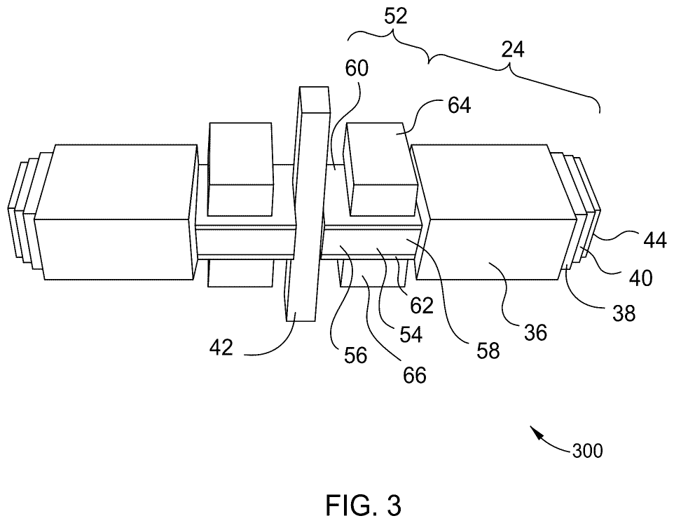

FIG. 3 is a perspective view of a mirrored DRAM pair 300 according to some examples of the present disclosure. In one or more embodiments, the 3D DRAM cells of FIG. 3 are like the 3D DRAM cells of FIG. 2, and common description is omitted for brevity. A DRAM cell includes an n-type transistor 52 (e.g., corresponding to n-type transistor 2) and a capacitor 24 (e.g., corresponding to capacitor 4). The n-type transistor 52 includes a semiconductor material 54 that forms the active region of the n-type transistor 52. The semiconductor material 54 may generally un-doped or lightly p-doped, for example. A drain region 56 (e.g., corresponding to first node 6) and a source region 58 (e.g., corresponding to second node 10) are disposed in the semiconductor material 54 with a channel region between the drain region 56 and the source region 58 in the semiconductor material 54. The drain region 56 and the source region 58 are n-doped in this example. A top gate dielectric layer 60 is disposed on the semiconductor material 54 (e.g., on a top surface of the semiconductor material 54), and a bottom gate dielectric layer 62 is disposed on the semiconductor material 54 on a side opposite from the top gate dielectric layer 60 (e.g., on a bottom surface of the semiconductor material 54). A top gate electrode 64 (e.g., corresponding to gate node 12) is disposed on (e.g., over) the top gate dielectric layer 60, and a bottom gate electrode 66 (e.g., corresponding to gate node 12) is disposed on (e.g., below) the bottom gate dielectric layer 62.

The capped end of the outer plate 36 (e.g., corresponding to a first terminal of capacitor 4) contacts the source region 58 of the n-type transistor 52 to electrically connect the source region 58 to the capacitor 24. The bitline contact 42 (e.g., corresponding to BL node 8) is disposed laterally contacting the drain region 56 of the n-type transistor 52.

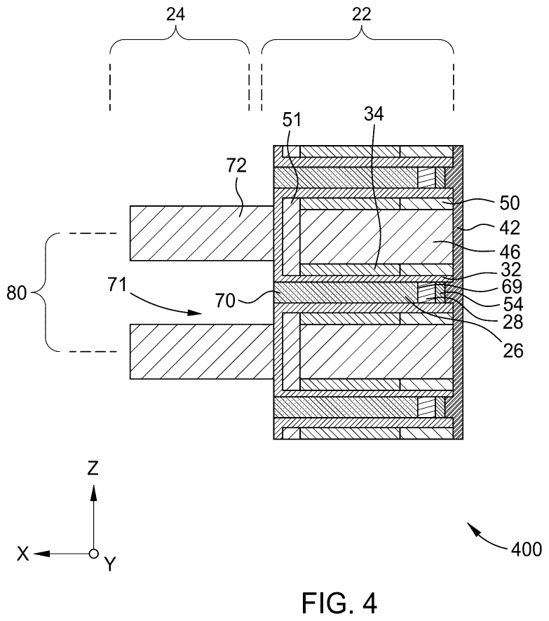

FIGS. 4 through 9 are cross-sectional views of intermediate structures during a method to form memory devices, such as 3D DRAM cells, according to some examples of the present disclosure. The memory devices formed according to the first method of FIGS. 4 through 9 can be substantially like those shown in FIG. 3, or portions of those shown in FIG. 3. The stacked semiconductor structures illustrated in FIGS. 4 through 9 are for illustrative purposes only. It is understood that the semiconductor structures and corresponding materials may be different based on the process integration flow.

Referring to FIG. 4, a stacked semiconductor structure 400 according to some examples of the present disclosure are illustrated. In one or more embodiments, the stacked semiconductor structure 400 is a partially-formed memory device, such as one or more 3D DRAM cells of a set of 3D DRAM cells of a 3D DRAM device. A full set of 3D DRAM cells can include many additional cells stacked vertically (e.g., more than five, and up to one hundred or more cells) in the z-direction, and be formed on a substrate that forms a plane in the x-direction and y-direction, which is not shown for clarity. The stacked semiconductor structure 400 includes at least portions of a memory device.

In one or more embodiments the stacked semiconductor structure 400 is a partially-formed memory device. The stacked semiconductor structure 400 includes an n-type transistor 22 and a capacitor 24, which are in the process of being formed. In one or more embodiments, capacitor 24 is a capacitor portion of a unit stack 80. In one or more embodiments, n-type transistor 22 may be or be referred to as a transistor, and is a transistor portion of the unit stack 80. In one or more embodiments, n-type transistor 22 may be a p-type transistor.

The transistor 22 portion of stacked semiconductor structure 400 includes a semiconductor layer 26, a first dielectric layer 32, a gate electrode 34, and a dielectric layer 46. As can be seen for stacked semiconductor structure 400, a full unit stack 80 is illustrated, as well as portions of two unit stacks. Although described with reference to a single gate-type structure (e.g., with reference to FIG. 2), stacked semiconductor structure 400 is illustrated having two gates (e.g., with reference to FIG. 3). In one or more embodiments, the operations described herein can be applied to a single gate-type structure. In some embodiments, the operations described herein can be applied to a two-gate type structure. In other embodiments, the operations described herein can be applied to a gate-all-around (GAA) structure (e.g., a four-gate type structure). In still other embodiments, the operations described herein can be applied to memory devices employing a combination of these structures, or other structures. In one or more embodiments, repeating the unit stack 80 of the film stack can enable forming additional layers of a memory device, including 3D DRAM cells. Also, using one instance of the unit stack in the film stack can enable forming one layer of 3D DRAM cells.

Gate electrode 34 is connected to a gate node of transistor 22, and gate electrode 34 may also be referred to as a gate node herein. Gate electrode 34 is formed on a first dielectric layer 32 formed on semiconductor layer 26. First dielectric layer 32 may also be or be referred to as a gate dielectric or gate oxide, and be any suitable high dielectric constant (high-K dielectric) material of a suitable thickness for a field effect transistor device. Gate electrode 34 can be deposited by any appropriate deposition technique, such as a conformal deposition process, such as ALD.

In some embodiments, semiconductor layer 26 is silicon (e.g., single crystalline, amorphous, or polycrystalline, which may be un-doped or lightly p-doped) or InGaZnO. Semiconductor layer 26 can be deposited by any appropriate deposition technique, such as epitaxial, or the like. In one or more embodiments, semiconductor layer 26 is formed by depositing a stack of silicon and silicon germanium layers (e.g., alternating layers formed by epitaxial deposition), where the silicon germanium layers are sacrificial and removed to leave behind the crystalline silicon layers.

In some embodiments, first dielectric layer 32 is silicon oxide, silicon oxynitride, another suitable dielectric material, such as a high-K dielectric) material. In one or more embodiments, first dielectric layer 32 can be deposited by any appropriate deposition technique, such as a conformal deposition process, such as atomic layer deposition (ALD). In one or more embodiments, the first dielectric layer 32 is an oxide formed by an oxidation process (e.g., by oxidizing exposed surfaces of the semiconductor layer 26).

In some embodiments, gate electrode 34 is any appropriately conducting material, such as a metal (e.g., tungsten or molybdenum), or a metal composite (e.g., titanium nitride), or polysilicon (n-type or p-type doped). In one or more embodiments, gate electrode 34 can be deposited by any appropriate deposition technique, such as a conformal deposition process, such as ALD. Although not illustrated for the stacked semiconductor structure 400, one or more gate barrier/tuning layers can optionally be formed on the first dielectric layer 32 prior to formation of the gate electrode 34, for example using a conformal deposition process, such as ALD.

In some embodiments, dielectric layer 46 is silicon dioxide, silicon nitride, another suitable dielectric material, such as low-k or high-k dielectric materials, or a combination of several materials. In one or more embodiments, dielectric layer 46 can be deposited by any appropriate deposition technique, such as a conformal deposition process, such as atomic layer deposition (ALD).

In one or more embodiments, transistor 22 also includes dielectric fill 50 and dielectric fill 51 (which may be referred to as a gate electrode fill). In some embodiments, dielectric fill 50, dielectric fill 51, or both, are a same material as or formed as part of dielectric layer 46. Dielectric fill 50 and dielectric fill 51 can be deposited by any appropriate deposition technique, such as a conformal deposition process, such as ALD or chemical vapor deposition (CVD), or a flowable deposition process, such as flowable CVD (FCVD).

Bitline node 42 is a contact along a vertical axis (z-direction). In one or more embodiments, bitline node 42 is along a vertical axis (z-direction) around which DRAM pairs are mirrored.

The capacitor 24 portion of stacked semiconductor structure 400 includes a second dielectric layer 72. A single unit stack 80 can include two portions of second dielectric layer 72. In one or more embodiments, prior to stacked semiconductor structure 400, a stack of material including a first set of dielectric layers (including second dielectric layer 72) and semiconductor layers (including semiconductor layer 26). The semiconductor layers (including semiconductor layer 26) can be pulled back laterally to expose a second lateral end 70 of the semiconductor layer 26. On the other hand, a first lateral end 69 of the semiconductor layer 26 that is opposite the second lateral end 70 is coupled to the bitline node 42. The pull back process can be any appropriate isotropic etch that selectively etches the semiconductor layers (including semiconductor layer 26) to leave behind the first set of dielectric layers (including second dielectric layer 72), and form a lateral recess 71.

In one or more embodiments, the first set of dielectric layers (including second dielectric layer 72) can be etched to thin the thickness of each dielectric layer to obtain a desired or appropriate size, for example after the pull back process that selectively etches the semiconductor layers.

In one or more embodiments, a second set of one or more sacrificial layers can be deposited between the dielectric layers and the semiconductor layers. In some embodiments, the second set of one or more sacrificial layers can be a dielectric different from the first set of dielectric layers. The second set of one or more sacrificial layers can then be selectively etched (e.g., before or after selectively etching the semiconductor layers), to remove these sacrificial layers.

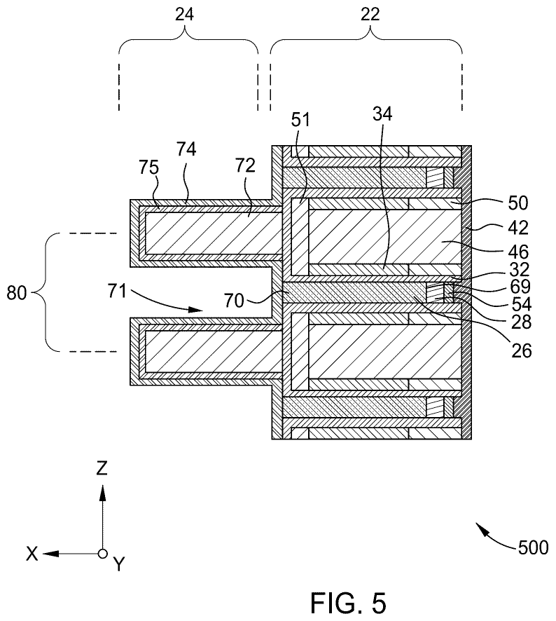

Referring to FIG. 5, a stacked semiconductor structure 500 according to some examples of the present disclosure are illustrated. In one or more embodiments, stacked semiconductor structure 500 is illustrated following the deposition of a doped silicon layer 74.

Doped silicon layer 74 can be deposited by any appropriate deposition technique, such as a conformal deposition process, such as ALD or CVD. The doped silicon layer 74 may be a doped amorphous, polysilicon, or polycrystalline silicon layer. In one or more embodiments, an undoped silicon layer 75 may be optionally deposited prior to the deposition of the doped silicon layer 74. The undoped silicon layer 75 can be deposited by any appropriate deposition technique, such as a conformal deposition process, such as ALD or CVD. In one or more embodiments, the undoped silicon layer 75 is an undoped amorphous or polycrystalline silicon layer.

In one or more embodiments, the doped silicon layer 74 has a thickness (e.g., an average thickness) between 3 nanometers and 50 nanometers. In some embodiments, the doped silicon layer 74 has a thickness (e.g., an average thickness) of about 5 nanometers, for example over the portion of the doped silicon layer 74 contacting the second lateral end 70 of the semiconductor layer 26. In embodiments in which the undoped silicon layer 75 is also deposited, the sum of the thicknesses of the undoped silicon layer 75 and the doped silicon layer 74 is no more than 50 nanometers.

In one or more embodiments, the doped silicon layer 74 is doped with phosphorous. In one or more embodiments, the doped silicon layer 74 is doped with arsenic. In other embodiments, the doped silicon layer 74 is doped with any suitable n-type dopant, for example antimony. In other embodiments, the doped silicon layer 74 is doped with any suitable p-type dopant, for example boron, gallium, or indium. In one or more embodiments, the doped silicon layer 74 is doped with about 1×10²¹ atoms (e.g., phosphorous or arsenic) per cubic centimeter. In one or more embodiments, the doped silicon layer 74 is doped with about 5×10²⁰ atoms to about 2×10²¹ atoms per cubic centimeter. In some embodiments, greater than about 2×10²¹ atoms per cubic centimeter is used.

In one or more embodiments, a native oxide precleaning process may be performed on the stacked semiconductor structure 400 prior to the formation of the doped silicon layer 74 as illustrated in the stacked semiconductor structure 500.

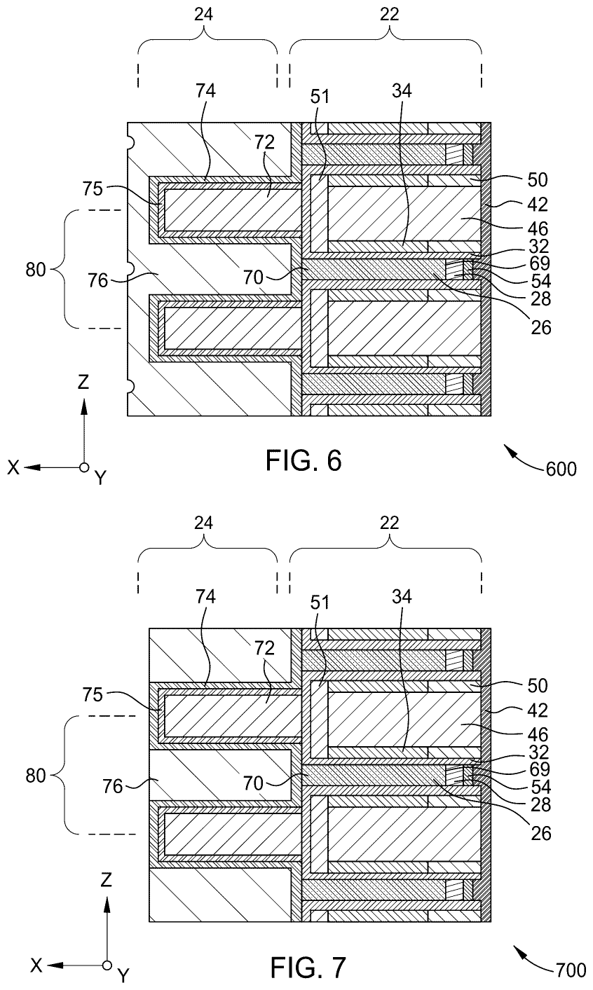

Referring to FIG. 6, a stacked semiconductor structure 600 according to some examples of the present disclosure are illustrated. In one or more embodiments, stacked semiconductor structure 600 is illustrated following the deposition of a third dielectric layer 76, which may be any suitable sacrificial material. In one or more embodiments, the third dielectric layer 76 is silicon nitride. In one or more embodiments, the third dielectric layer 76 is aluminum oxide. In other embodiments, the third dielectric layer 76 can be SiON, SiCN, SiOCN, SiOC, SiGe, carbon, aluminum oxide, silicon, titanium nitride, Mo, or tungsten. The third dielectric layer 76 can be deposited by any appropriate deposition technique, such as a conformal deposition process, such as ALD or CVD.

Referring to FIG. 7, a stacked semiconductor structure 700 according to some examples of the present disclosure are illustrated. In one or more embodiments, stacked semiconductor structure 700 is illustrated following the etching of the third dielectric layer 76 to expose the doped silicon layer 74. In one or more embodiments, the third dielectric layer 76 is isotopically etched to separate the third dielectric layer 76 vertically and to expose the sidewall of the doped silicon layer 74.

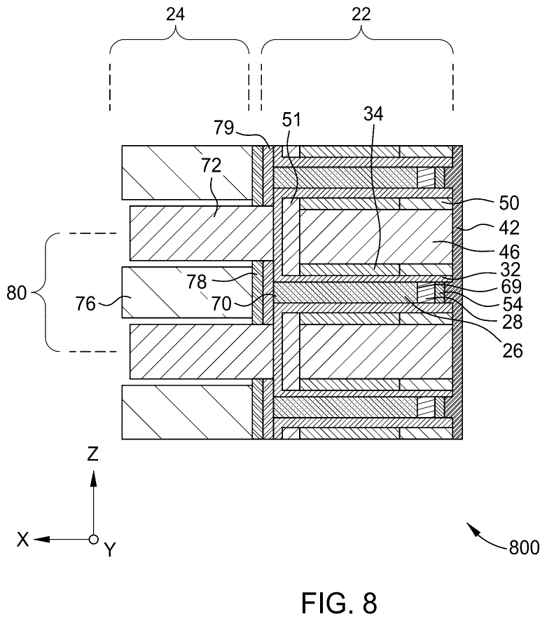

Referring to FIG. 8, a stacked semiconductor structure 800 according to some examples of the present disclosure are illustrated. In one or more embodiments, the stacked semiconductor structure 700 is illustrated following the pulling back of the lateral portions of the doped silicon layer 74, leaving a vertical portion 78 of the doped silicon layer 74 on the second lateral end 70 of the semiconductor layer 26. In one or more embodiments, if the optional undoped silicon layer 75 is deposited, the lateral portions of the undoped silicon layer 75 are also pulled back and a vertical portion 79 of the undoped silicon layer 75 also remains on the second lateral end 70 of the semiconductor layer 26. The pull back process can be any appropriate etch process that selectively etches the undoped silicon layer 75 (if deposited) and the doped silicon layer 74. For example, the etch process can use an ion screen for enhanced selectivity while etching using predominantly radicals.

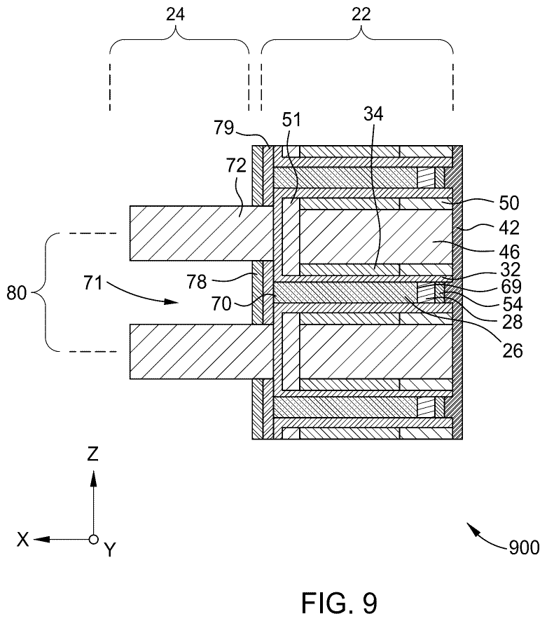

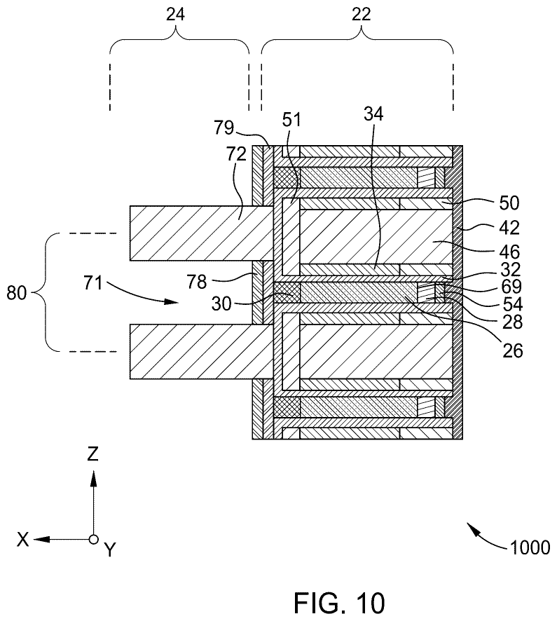

Referring to FIG. 9, a stacked semiconductor structure 900 according to some examples of the present disclosure are illustrated. In one or more embodiments, stacked semiconductor structure 900 is illustrated following the removal of the third dielectric layer 76. The removal (or pull back) of the third dielectric layer 76 can be any appropriate isotropic etch that selectively etches the third dielectric layer 76. For example, when the third dielectric layer 76 is silicon nitride, a hot phosphoric acid etch process can be used to pull back the third dielectric layer 76. Other isotropic etch process can be used for silicon nitride, or when the third dielectric layer 76 is formed of another dielectric material.

Referring to FIG. 10, a stacked semiconductor structure 1000 according to some examples of the present disclosure are illustrated. In one or more embodiments, stacked semiconductor structure 1000 is illustrated following drive-in of dopant from the vertical portion 78 of the doped silicon layer 74 into the vertical portion 79 of the optional underlying undoped silicon layer 75 (if deposited) and/or the semiconductor layer 26 to create a doped region, second region 30, by performing a thermal annealing process. By using a thermal annealing process, dopant (e.g., an n-type dopant, for example phosphorous, arsenic, or antimony, or a p-type dopant, for example boron, gallium, or indium) diffuses in, and can form a deeper gradient profile as a lightly doped drain (LDD), which can reduce gate induced drain leakage in the transistor 22. In other embodiments, the drive in thermal anneal may be skipped if an abrupt junction is desired per device need. In yet another embodiment, a different thermal anneal may be performed to activate the dopants in the silicon layers.

In one or more embodiments, performing the thermal annealing process includes performing a rapid thermal processing procedure. In one or more embodiments, performing the thermal annealing process includes applying heat to the stacked semiconductor structure 900 between 600 degrees centigrade and 1100 degrees centigrade for a period of time between less than 1 second to about 30 minutes. According to one or more embodiments, a rapid thermal processing procedure is used having a higher temperature, for example higher temperature than 600 degrees centigrade, lower temperature than 1100 degrees centigrade, or both, applied to the doped silicon layer 74 on the second lateral end 70 of the semiconductor layer 26. According to one or more embodiments, a rapid thermal processing procedure is used having a lower temperature, for example lower temperature than 600 degrees centigrade and no more than 1100 degrees centigrade applied to the doped silicon layer 74 on the second lateral end 70 of the semiconductor layer 26. According to one or more embodiments, the rapid thermal processing procedure is performed over a period of time between less than 1 second and 30 minutes.

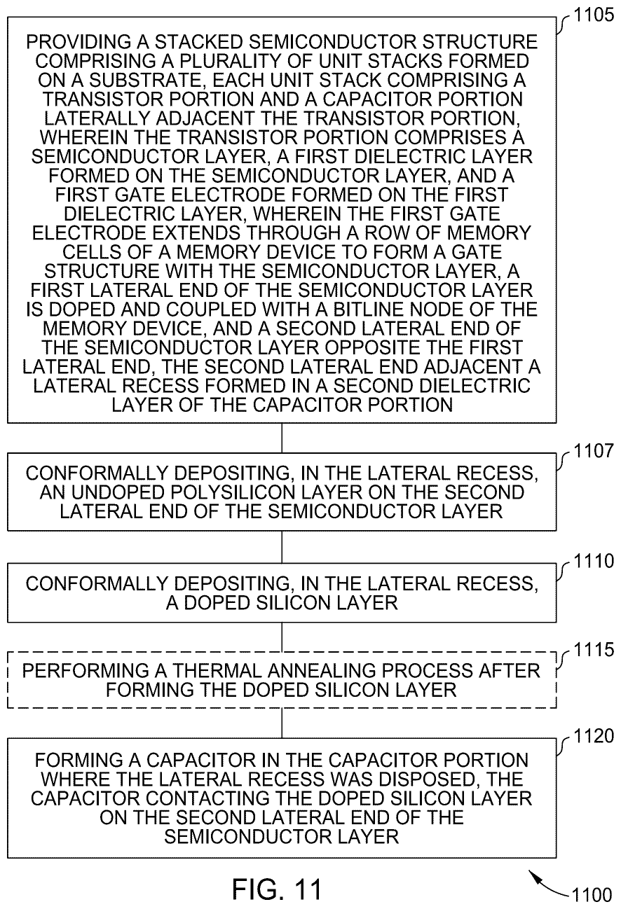

FIG. 11 is a flow diagram of a method 1100 of semiconductor processing, according to some examples of the present disclosure. In one or more embodiments, method 1100 includes one or more operations of a memory device fabrication process, for example the fabrication of a 3D DRAM. In one or more embodiments, method 1100 includes one or more operations described herein, for example with reference to one or more of FIG. 1 through FIG. 10.

Operation 1105 of the method 1100 includes providing a stacked semiconductor structure comprising a plurality of unit stacks formed on a substrate, each unit stack 80 comprising the transistor 22 portion and the capacitor 24 portion laterally adjacent the transistor 22 portion. In one or more embodiments, the transistor 22 portion comprises the semiconductor layer 26, the first dielectric layer 32 formed on the semiconductor layer 26, and the gate electrode 34 formed on the first dielectric layer 32. The gate electrode 34 extends through a row of memory cells of a memory device to form a gate structure with the semiconductor layer 26. A first lateral end 69 of the semiconductor layer 26 is doped and coupled with the bitline node 42 of the memory device. A second lateral end 70 of the semiconductor layer 26 is opposite the first lateral end 69. The second lateral end is adjacent to a lateral recess 71 formed in a second dielectric layer 72 of the capacitor 24 portion.

Operation 1107 of the method 1100 includes conformally depositing, in the lateral recess 71, the undoped silicon layer 75 on the second lateral end 70 of the semiconductor layer 26. In one or more embodiments, operation 1107 is optional.

Operation 1110 of the method 1100 includes conformally depositing the doped silicon layer 74. The doped silicon layer 74 is deposited in the lateral recess 71. If the undoped silicon layer 75 is deposited, the doped silicon layer 74 is deposited over the undoped silicon layer 75. If the undoped silicon layer 75 is not deposited, the doped silicon layer 74 is deposited on the second lateral end 70 of the semiconductor layer 26.

Operation 1115 of the method 1100 includes performing a thermal annealing process after depositing the doped silicon layer 74. In one or more embodiments, operation 1115 is optional.

Operation 1120 of the method 1100 includes forming a capacitor 24 in the capacitor 24 portion where the lateral recess 71 was disposed, the capacitor 24 contacting the doped silicon layer 74 on the second lateral end 70 of the semiconductor layer 26 (or the optional undoped silicon layer 75).

In one or more embodiments, the method 1100 includes forming a third dielectric layer 76 on the doped silicon layer 74 in the lateral recess 71, the doped silicon layer 74 including a vertical portion 78 on the second lateral end 70 and lateral portions coupled with the vertical portion 78. The lateral portions of the doped silicon layer are pulled back, and the third dielectric layer 76 is pulled back to expose the vertical portion 78 of the doped silicon layer 74. In one or more embodiments, pulling back the vertical portion 78 and the lateral portions of the doped silicon layer includes removing portions of the doped silicon layer 74 between the third dielectric layer 76 and the second dielectric layer 72. In one or more embodiments, the third dielectric layer 76 comprises silicon nitride, aluminum oxide, or a combination of both silicon nitride and aluminum oxide. In one or more embodiments, if the optional undoped silicon layer 75 is deposited, the pull back process also includes removing portions of the undoped silicon layer 75 between the third dielectric layer 76 and the second dielectric layer 72 leaving the vertical portion 79 of the undoped silicon layer 75.

In one or more embodiments, performing the thermal annealing process includes performing a rapid thermal processing procedure after forming the doped silicon layer 74 on the second lateral end 70. In one or more embodiments, performing the thermal annealing process includes applying heating to the stacked semiconductor structure of at least 600 degrees centigrade and no more than 1100 degrees centigrade for a time period between less than 1 second and about 30 minutes. According to one or more embodiments, a rapid thermal processing procedure is used having a higher or lower temperature, for example a higher temperature than 1100 degrees centigrade or lower temperature than 600 degrees centigrade applied to the doped silicon layer 74 on the second lateral end 70 of the semiconductor layer 26 (or the optional undoped silicon layer 75).

In one or more embodiments, the doped silicon layer 74 has a thickness (e.g., an average thickness) between 3 nanometers and 50 nanometers. In some embodiments, the doped silicon layer 74 has a thickness (e.g., an average thickness) of about 5 nanometers, for example over the portion of the doped silicon layer 74 contacting the second lateral end 70 of the semiconductor layer 26. In embodiments in which the undoped silicon layer 75 is also deposited, the sum of the thicknesses of the undoped silicon layer 75 and the doped silicon layer 74 is no more than 50 nanometers.

In one or more embodiments, the doped silicon layer 74 is doped with phosphorous. In one or more embodiments, the doped silicon layer 74 is doped with arsenic. In other embodiments, the doped silicon layer 74 is doped with any suitable n-type dopant, for example antimony. In other embodiments, the doped silicon layer 74 is doped with any suitable p-type dopant, for example boron, gallium, or indium. In one or more embodiments, the doped silicon layer 74 is doped with at least 1×10²⁰ atoms (e.g., phosphorous or arsenic) per cubic centimeter.

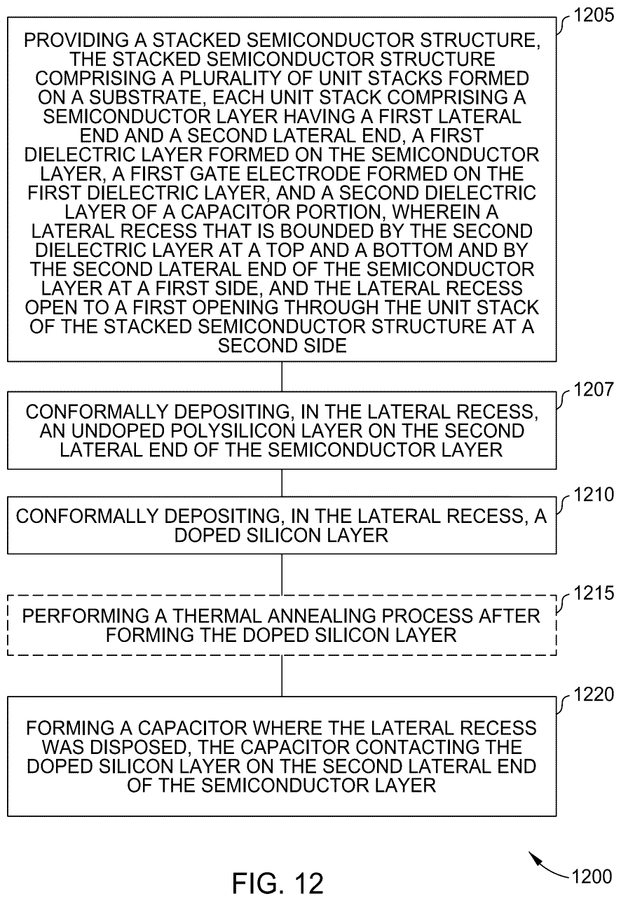

FIG. 12 is a flow diagram of a method 1200 of semiconductor processing, according to one or more embodiments. In one or more embodiments, method 1200 includes one or more operations of a memory device fabrication process, for example the fabrication of a 3D DRAM. In one or more embodiments, method 1200 includes one or more operations described herein, for example with reference to one or more of FIG. 1 through FIG. 11.

Operation 1205 of the method 1200 includes providing a stacked semiconductor structure, the stacked semiconductor structure including a plurality of unit stacks formed on a substrate. Each unit stack 80 of the plurality of unit stacks includes a semiconductor layer 26 having a first lateral end 69 and a second lateral end 70. A first dielectric layer 32 of the unit stack 80 is formed on the semiconductor layer 26. The gate electrode 34 of the unit stack 80 is formed on the first dielectric layer 32. The unit stack 80 also includes a second dielectric layer 72 of a capacitor 24 portion. A lateral recess 71 is bounded by the second dielectric layer 72 at a top and a bottom and by the second lateral end 70 of the semiconductor layer 26 at a first side. The lateral recess 71 is open to a first opening through the unit stack 80 of the stacked semiconductor structure at a second side.

Operation 1207 of the method 1200 includes conformally depositing, in the lateral recess 71, the undoped silicon layer 75 on the second lateral end 70 of the semiconductor layer 26. In one or more embodiments, operation 1107 is optional.

Operation 1210 of the method 1200 includes conformally depositing the doped silicon layer 74. The doped silicon layer 74 is deposited in the lateral recess 71. If the undoped silicon layer 75 is deposited, the doped silicon layer 74 is deposited over the undoped silicon layer 75. If the undoped silicon layer 75 is not deposited, the doped silicon layer 74 is deposited on the second lateral end 70 of the semiconductor layer 26.

Operation 1215 of the method 1200 includes performing a thermal annealing process after forming the doped silicon layer on the second lateral end. In one or more embodiments, operation 1215 is optional.

Operation 1220 of the method 1200 includes forming a capacitor 24 where the lateral recess 71 was disposed, the capacitor 24 contacting the doped silicon layer 74 on the second lateral end 70 of the semiconductor layer 26.

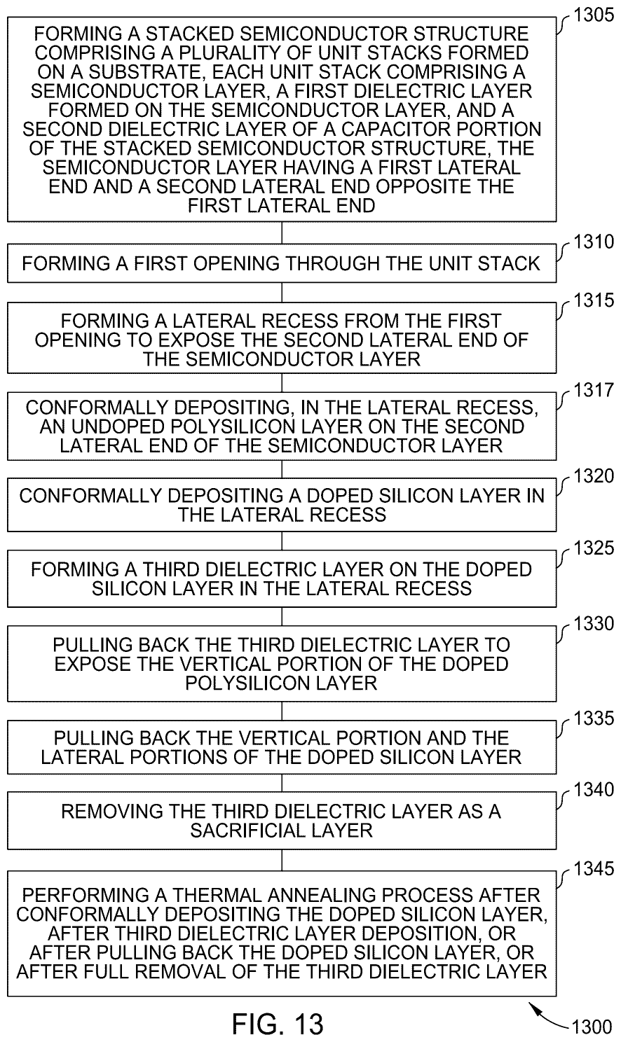

FIG. 13 is a flow diagram of a method 1300 of semiconductor processing, according to one or more embodiments. In one or more embodiments, method 1300 includes one or more operations of a memory device fabrication process, for example the fabrication of a 3D DRAM. In one or more embodiments, method 1300 includes one or more operations described herein, for example with reference to one or more of FIG. 1 through FIG. 12.

Operation 1305 of the method 1300 includes forming a stacked semiconductor structure comprising a plurality of unit stacks formed on a substrate, where each unit stack 80 includes a semiconductor layer 26, a first dielectric layer 32 formed on the semiconductor layer 26, and a second dielectric layer 72 of a capacitor 24 portion of the stacked semiconductor structure. The semiconductor layer 26 has a first lateral end 69 and a second lateral end 70 opposite the first lateral end 69.

Operation 1310 of the method 1300 includes forming a first opening through the unit stack 80.

Operation 1315 of the method 1300 includes forming a lateral recess 71 from the first opening to expose the second lateral end 70 of the semiconductor layer 26.

Operation 1317 of the method 1300 includes conformally depositing, in the lateral recess 71, the undoped silicon layer 75 on the second lateral end 70 of the semiconductor layer 26. In one or more embodiments, operation 1317 is optional.

Operation 1320 of the method 1300 includes conformally depositing the doped silicon layer 74 in the lateral recess 71. The doped silicon layer includes a vertical portion 78 on the second lateral end 70 (or a vertical portion 79 of the undoped silicon layer 75) and lateral portions coupled with the vertical portion 78.

Operation 1325 of the method 1300 includes forming a third dielectric layer 76 on the doped silicon layer 74 in the lateral recess 71.

Operation 1330 of the method 1300 includes pulling back the third dielectric layer 76 to expose the vertical portion 78 of the doped silicon layer 74.

Operation 1335 of the method 1300 includes pulling back the vertical portion 78 and the lateral portions of the doped silicon layer 74 (and the optional undoped silicon layer 75, if deposited).

Operation 1340 of the method 1300 includes removing the third dielectric layer 76 as a sacrificial layer.

Operation 1345 of the method 1300 includes performing a thermal annealing process after conformally depositing the doped silicon layer 74, after third dielectric layer 76 deposition, or after pulling back the doped silicon layer 74, or after full removal of the sacrificial third dielectric layer 76.

It is contemplated that various subject matter disclosed herein may be combined. As an example, one or more aspects, features, components, and/or properties of the DRAM cell 100, mirrored DRAM pairs 200 through 300, stacked semiconductor structures 400 through 1000, and/or methods 1100 through 1300 may be combined. Moreover, it is contemplated that various subject matter disclosed herein may include some or all of the aforementioned benefits.

While the foregoing is directed to embodiments of the present disclosure, other and further embodiments of the disclosure may be devised without departing from the basic scope thereof. The present disclosure also contemplates that one or more aspects of the embodiments described herein may be substituted in for one or more of the other aspects described. The scope of the disclosure is determined by the claims that follow.

1. A method for semiconductor processing, comprising:
providing a stacked semiconductor structure comprising a plurality of unit stacks formed on a substrate, each unit stack comprising a transistor portion and a capacitor portion laterally adjacent the transistor portion, wherein the transistor portion comprises a semiconductor layer, a first dielectric layer formed on the semiconductor layer, and a first gate electrode formed on the first dielectric layer, wherein the first gate electrode extends through a row of memory cells of a memory device to form a gate structure with the semiconductor layer, a first lateral end of the semiconductor layer is doped and coupled with a bitline node of the memory device, and a second lateral end of the semiconductor layer opposite the first lateral end, the second lateral end adjacent a lateral recess formed in a second dielectric layer of the capacitor portion;
conformally depositing, in the lateral recess, a doped silicon layer on the second lateral end of the semiconductor layer;
performing an optional thermal annealing process after forming the doped silicon layer on the second lateral end; and
forming a capacitor in the capacitor portion where the lateral recess was disposed, the capacitor contacting the doped silicon layer on the second lateral end of the semiconductor layer.

2. The method of claim 1, further comprising:
forming a third dielectric layer on the doped silicon layer in the lateral recess, the doped silicon layer including a vertical portion on the second lateral end and lateral portions coupled with the vertical portion;
pulling back the vertical portion and the lateral portions of the doped silicon layer; and
pulling back the third dielectric layer to expose the vertical portion of the doped silicon layer.

3. The method of claim 2, wherein the third dielectric layer comprises silicon nitride, aluminum oxide, or a combination thereof.

4. The method of claim 2, wherein pulling back the vertical portion and the lateral portions of the doped silicon layer comprise removing portions of the doped silicon layer between the third dielectric layer and the second dielectric layer.

5. The method of claim 1, wherein performing the thermal annealing process comprises:
performing a rapid thermal processing procedure after forming the doped silicon layer on the second lateral end.

6. The method of claim 1, wherein performing the thermal annealing process comprises:
applying heating to the stacked semiconductor structure of at least 600 degrees centigrade and no more than 1100 degrees centigrade for a time period between less than 1 second and 30 minutes.

7. The method of claim 1, wherein the doped silicon layer comprises an average thickness between 3 nanometers and 50 nanometers.

8. The method of claim 1, wherein the doped silicon layer comprises polysilicon doped with phosphorous, arsenic, or a combination thereof.

9. The method of claim 8, wherein the doped silicon layer comprises polysilicon with a doping concentration comprising at least 1×10²⁰ phosphorous atoms per cubic centimeter.

10. A method for semiconductor processing, comprising:
providing a stacked semiconductor structure, the stacked semiconductor structure comprising a plurality of unit stacks formed on a substrate, each unit stack comprising a semiconductor layer having a first lateral end and a second lateral end, a first dielectric layer formed on the semiconductor layer, a first gate electrode formed on the first dielectric layer, and a second dielectric layer of a capacitor portion, wherein a lateral recess that is bounded by the second dielectric layer at a top and a bottom and by the second lateral end of the semiconductor layer at a first side, and the lateral recess open to a first opening through the unit stack of the stacked semiconductor structure at a second side;
conformally depositing, in the lateral recess, a doped silicon layer on the second lateral end of the semiconductor layer;
performing a thermal annealing process after forming the doped silicon layer on the second lateral end; and
forming a capacitor where the lateral recess was disposed, the capacitor contacting the doped silicon layer on the second lateral end of the semiconductor layer.

11. The method of claim 10, further comprising:
forming a third dielectric layer on the doped silicon layer in the lateral recess, the doped silicon layer including a vertical portion on the second lateral end and lateral portions coupled with the vertical portion;
pulling back the vertical portion and the lateral portions of the doped silicon layer; and
pulling back the third dielectric layer to expose the vertical portion of the doped silicon layer.

12. The method of claim 11, wherein the third dielectric layer comprises silicon nitride, aluminum oxide, or a combination thereof.

13. The method of claim 11, wherein pulling back the vertical portion and the lateral portions of the doped silicon layer comprise removing portions of the doped silicon layer between the third dielectric layer and the second dielectric layer.

14. The method of claim 10, wherein performing the thermal annealing process comprises:
performing a rapid thermal processing procedure after forming the doped silicon layer on the second lateral end.

15. The method of claim 10, wherein performing the thermal annealing process comprises:
applying heating to the stacked semiconductor structure of at least 600 degrees centigrade and no more than 1100 degrees centigrade for a time period between less than 1 second and 30 minutes.

16. The method of claim 10, wherein the doped silicon layer comprises polysilicon doped with phosphorous, arsenic, or a combination thereof.

17. A method for semiconductor processing, comprising:
forming a stacked semiconductor structure comprising a plurality of unit stacks formed on a substrate, each unit stack comprising a semiconductor layer, a first dielectric layer formed on the semiconductor layer, and a second dielectric layer of a capacitor portion of the stacked semiconductor structure, the semiconductor layer having a first lateral end and a second lateral end opposite the first lateral end;
forming a first opening through the unit stack;
forming a lateral recess from the first opening to expose the second lateral end of the semiconductor layer;
conformally depositing a doped silicon layer in the lateral recess, including a vertical portion on the second lateral end and lateral portions coupled with the vertical portion;
forming a third dielectric layer on the doped silicon layer in the lateral recess;
pulling back the third dielectric layer to expose the vertical portion of the doped silicon layer;
removing the third dielectric layer as a sacrificial layer;
pulling back the vertical portion and the lateral portions of the doped silicon layer; and
performing a thermal annealing process after conformally depositing the doped silicon layer, after third dielectric layer deposition, or after pulling back the doped silicon layer, or after full removal of the third dielectric layer.

18. The method of claim 17, further comprising:
forming a capacitor where the lateral recess was disposed, the capacitor contacting the doped silicon layer on the second lateral end of the semiconductor layer.

19. The method of claim 17, further comprising:
performing a rapid thermal processing procedure after forming the doped silicon layer on the second lateral end.

20. The method of claim 17, wherein the doped silicon layer comprises an average thickness of at least 3 nanometers and no more than 20 nanometers, comprises polysilicon with a doping concentration comprising at least 1×10²⁰ phosphorous atoms per cubic centimeter.
